(19) United States
(12) Patent Application Publication
(10) Pub. No.: US 2025/0142805 A1
(43) Pub. Date: May 1, 2025

(54) SEMICONDUCTOR MEMORY DEVICE

(71) Applicant: Samsung Electronics Co., Ltd., Suwon-si (KR)

(72) Inventors: Jung Kun LIM, Suwon-si (KR); Young Chul LIM, Suwon-si (KR); Gi Duck KWEON, Suwon-si (KR); Hyo Joong KIM, Suwon-si (KR)

(73) Assignee: Samsung Electronics Co., Ltd., Suwon-si (KR)

(21) Appl. No.: 18/784,296

(22) Filed: Jul. 25, 2024

(30) Foreign Application Priority Data
Oct. 27, 2023 (KR) 10-2023-0145761

(51) Int. Cl. H10B 12/00

(52) U.S. Cl. CPC H10B 12/30; H10B 12/03

(57) ABSTRACT

A semiconductor memory device includes a semiconductor pattern on the substrate, and extending in a first horizontal direction, a bit-line and a first electrode of an information storage element electrically connected to two opposite ends of the semiconductor pattern, respectively, and a gate electrode on the semiconductor pattern, wherein the first electrode includes a first area and a second area spaced apart from each other in a vertical direction, and a connection area connecting the first area with the second area, wherein each of the first area and the second area includes first and second extensions spaced apart from each other in the vertical direction, and a connection portion connecting the first extension and the second extension and separated from the connection area, and wherein the connection area connects the second extension of the first area and the first extension of the second area adjacent to each other.

### CROSS-REFERENCE TO RELATED APPLICATION

This application claims priority from Korean Patent Application No. 10-2023-0145761 filed on Oct. 27, 2023, in the Korean Intellectual Property Office, and all the benefits accruing therefrom under 35 U.S.C. 119, the contents of which in its entirety are herein incorporated by reference.

### BACKGROUND

### Field

The present disclosure relates to semiconductor memory devices.

### Description of Related Art

In a conventional two-dimensional or planar semiconductor device, integration thereof is mainly determined based on an area occupied by a unit memory cell, and is therefore greatly affected by a level of micropattern formation technology. However, ultra-expensive equipment is required for formation of a fine pattern. Thus, the integration of the 2D semiconductor device is increasing but is still limited. Accordingly, three-dimensional semiconductor memory devices having memory cells arranged three-dimensionally are being proposed.

### SUMMARY

An effect of the present disclosure is to provide a semiconductor memory devices with improved product reliability.

Effects in accordance with the present disclosure are not limited to the above-mentioned effect. Other effects and advantages in accordance with the present disclosure as not mentioned above may be understood from following descriptions and more clearly understood from the following example embodiments in accordance with the present disclosure. Further, it will be readily appreciated that the effect and advantages in accordance with the present disclosure may be realized by the features and a combinations of the features as recited in the claims.

According to an example embodiment of the present disclosure, a semiconductor memory device may include a semiconductor pattern on a substrate, and extending in a first direction parallel to an upper surface of the substrate, a bit-line electrically connected to a first end of the semiconductor pattern, a first electrode electrically connected to a second end of the semiconductor pattern, the second end of the semiconductor pattern being opposite to the first end of the semiconductor pattern, a second electrode on the first electrode, a dielectric film interposed between the first electrode and the second electrode, and a gate electrode on the semiconductor pattern, wherein the first electrode includes a first area and a second area spaced apart from each other in a second direction perpendicular to the upper surface of the substrate, and a connection area connecting the first area and the second area to each other, wherein each of the first area and the second area includes a first extension and a second extension spaced apart from each other in the second direction, and a connection portion connecting the first extension and the second extension to each other and physically separated from the connection area, and wherein the connection area connects the second extension of the first area and the first extension of the second area that are adjacent to each other to each other.

According to an example embodiment of the present disclosure, a semiconductor memory device includes a bit-line on a substrate, a semiconductor pattern extending from the bit-line in a first direction parallel to an upper surface of the substrate, a first mold pattern, a second mold pattern, and a third mold pattern sequentially arranged and spaced apart from each other in a second direction perpendicular to the upper surface of the substrate, each of the first mold pattern, the second mold pattern, and the third mold pattern extending in the first direction, each of the first mold pattern and the third mold pattern protruding in the first direction beyond the second mold pattern, and an information storage element on the first mold pattern, the second mold pattern, and the third mold pattern, the information storage element being electrically connected to the semiconductor pattern.

According to an example embodiment of the present disclosure, a semiconductor memory device includes a bit-line on a substrate, a semiconductor pattern extending from the bit-line in a first direction parallel to an upper surface of the substrate, a gate electrode on the semiconductor pattern, a first mold pattern, a second mold pattern, and a third mold pattern sequentially arranged and spaced apart from each other in a second direction perpendicular to the upper surface of the substrate, each of the first mold pattern, the second mold pattern, and the third mold pattern extending in the first direction, each of the first mold pattern and the third mold pattern protruding in the first direction beyond the second mold pattern, and an information storage element between the first mold pattern and the third mold pattern, and electrically connected to the semiconductor pattern, wherein the information storage element includes a first electrode including a first area between the first mold pattern and the second mold pattern, a second area between the second mold pattern and the third mold pattern, and a connection area on a side surface of the second mold pattern and connecting the first area and the second area to each other, a second electrode on the first electrode, and a dielectric film interposed between the first electrode and the second electrode, and wherein in a same etching process, each of an etch rate of the first mold pattern and an etch rate of the third mold pattern is different from an etch rate of the second mold pattern.

Specific details of some example embodiments are included in the detailed descriptions and drawings.

### BRIEF DESCRIPTION OF DRAWINGS

The above and other aspects and features of the present disclosure will become more apparent by describing in detail some example embodiments thereof with reference to the attached drawings, in which:

FIG. 1 is a schematic circuit diagram showing a cell array of a 3D semiconductor memory device according to an example embodiment;

FIG. 2 is an illustrative perspective view showing a semiconductor memory device according to an example embodiment;

FIG. 3 is a top view showing a semiconductor memory device according to an example embodiment;

FIG. 4 is a cross-sectional view cut along A-A in FIG. 3;

FIG. 5 is an enlarged view of a Q portion of FIG. 4;

FIG. 6 is a cross-sectional view cut along B-B in FIG. 3;

FIG. 7 is a diagram for illustrating a semiconductor memory device according to an example embodiment;

FIG. 8 is a diagram for illustrating a semiconductor memory device according to an example embodiment;

FIG. 9 is a diagram for illustrating a semiconductor memory device according to an example embodiment;

FIG. 10 is a diagram for illustrating a semiconductor memory device according to an example embodiment;

FIGS. 11 to 14 are respectively diagrams for illustrating semiconductor memory devices according to some example embodiments;

FIG. 15 is a schematic circuit diagram showing a cell array of a 3D semiconductor memory device according to an example embodiment;

FIG. 16 is an illustrative perspective view showing a semiconductor memory device according to an example embodiment;

FIG. 17 and FIG. 18 are diagrams for illustrating a semiconductor memory device according to some example embodiments; and

FIGS. 19 to 23 are diagrams for illustrating a method for manufacturing a semiconductor memory device according to an example embodiment.

### DETAILED DESCRIPTIONS

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C, or any combination thereof. Likewise, A and/or B means A, B, or A and B.

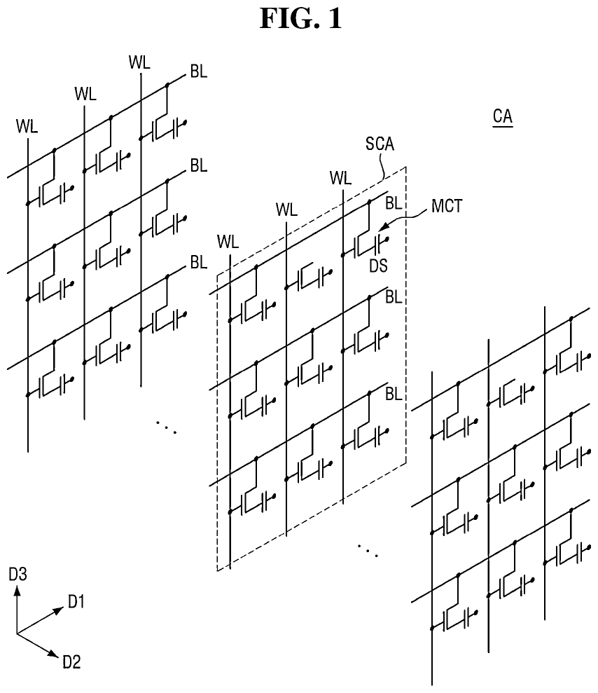

FIG. 1 is a schematic circuit diagram showing a cell array of a 3D semiconductor memory device according to an example embodiment.

Referring to FIG. 1, a cell array CA of a semiconductor memory device according to an example embodiment may include a plurality of sub-cell arrays SCA. In one example, the sub-cell arrays SCA may be arranged along a second direction D2.

Each sub-cell array SCA may include a plurality of bit-lines BL, a plurality of word-lines WL, and a plurality of memory cell transistors MCT. One memory cell transistor MCT may be disposed between one word-line WL and one bit-line BL.

The bit-lines BL may be conductive patterns (e.g., metal lines) stacked on the substrate in a third direction D3. Each bit-line BL may extend in a first direction D1. Adjacent bit-lines BL may be spaced apart from each other in the third direction D3.

The word-lines WL may be conductive patterns (e.g., metal lines) extending from the substrate in a perpendicular direction thereto (e.g., the third direction D3). The word lines WL within one sub-cell array SCA may be arranged in the first direction D1. The word lines WL adjacent to each other may be spaced apart from each other in the first direction D1.

A gate of the memory cell transistor MCT may be connected to the word-line WL, and a first source/drain of the memory cell transistor MCT may be connected to the bit-line BL. A second source/drain of the memory cell transistor MCT may be connected to an information storage element DS.

The information storage elements DS may be memory elements that may store data therein. Each information storage element DS may be a memory element using a capacitor, a memory element using a magnetic tunnel junction pattern, or a memory element using a variable resistor including a phase change material. In one example, each information storage element DS may be a capacitor.

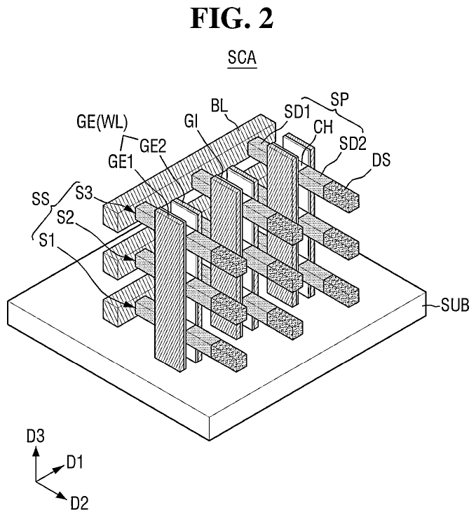

FIG. 2 is an illustrative perspective view showing a semiconductor memory device according to an example embodiment.

Referring to FIG. 1 and FIG. 2, one of the plurality of sub-cell arrays SCA as described with reference to FIG. 1 may be disposed on a substrate SUB.

Hereinafter, the first direction D1 and the second direction D2 may be parallel to an upper surface of the substrate SUB, and the third direction D3 may be a direction perpendicular to the upper surface of the substrate SUB. The first direction D1, the second direction D2, and the third direction D3 may be different directions. For example, the first direction D1, the second direction D2, and the third direction D3 may be perpendicular to each other.

The substrate SUB may be made of bulk silicon or silicon-on-insulator (SOI). In some example embodiments, the substrate SUB may be a silicon substrate or may include silicon germanium, silicon germanium on insulator (SGOI), indium antimonide, lead tellurium compound, indium arsenic, indium phosphide, gallium arsenide or gallium antimonide. However, the present disclosure is not limited thereto. In the following, an example in which the substrate SUB is embodied as a substrate including silicon is described.

A stack structure SS including first to third layers S1, S2, and S3 may be disposed on the substrate SUB. The first to third layers S1, S2, and S3 of the stack structure SS may be stacked while being spaced apart from each other in the third direction D3. In some example embodiments, the first to third layers S1, S2, and S3 of the stack structure SS may be stacked while being spaced apart from each other in the third direction D3. Each of the first to third layers S1, S2, and S3 may include a plurality of semiconductor patterns SP, a plurality of information storage elements DS, and a gate electrode GE.

The semiconductor pattern SP may have a line shape or a bar shape extending in the second direction D2. The semiconductor pattern SP may include a semiconductor material such as silicon, germanium, or silicon-germanium. In one example, the semiconductor pattern SP may include at least one of polysilicon, polysilicon germanium, single crystal silicon, or single crystal silicon-germanium.

Each semiconductor pattern SP may include a channel area CH, a first impurity area SD1, and a second impurity area SD2. The channel area CH may be interposed between the first and second impurity areas SD1 and SD2. The channel area CH may correspond to a channel of the memory cell transistor MCT as described with reference to FIG. 1. The first and second impurity areas SD1 and SD2 may correspond to the first source/drain and the second source/drain of the memory cell transistor MCT as described with reference to FIG. 1, respectively.

Each of the first and second impurity areas SD1 and SD2 may be an area in which impurities are doped into the semiconductor pattern SP. Accordingly, each of the first and second impurity areas SD1 and SD2 may have an n-type conductivity type or a p-type conductivity type, respectively. The first impurity area SD1 may be formed adjacent to a first end of the semiconductor pattern SP, and the second impurity area SD2 may be formed adjacent to a second end of the semiconductor pattern SP1. The second end may be opposite to the first end in the second direction D2.

The first impurity area SD1 may be formed adjacent to the bit-line BL. The first impurity area SD1 may be connected to the bit-line BL. The second impurity area SD2 may be formed adjacent to the information storage element DS. The second impurity area SD2 may be connected to the information storage element DS.

On the substrate SUB, a plurality of bit-lines BL extending in the first direction D1 may be disposed. Each bit-line BL may have a line shape or a bar shape extending in the first direction D1. The bit-lines BL may be arranged along the third direction D3. Each bit-line BL may be electrically connected to the first impurity areas SD1 of the semiconductor patterns SP arranged along the first direction D1.

The bit-line BL may include a conductive material, for example, any one of a doped semiconductor material, a conductive metal nitride, a metal, or a metal-semiconductor compound.

Among the first to third layers S1, S2, and S3, the first layer S1 is described in detail in a representative manner. The semiconductor patterns SP of the first layer S1 may be arranged to be spaced apart from each other in the first direction D1. The semiconductor patterns SP of the first layer S1 may be positioned at the same first level. The bit-line BL of the first layer S1 (e.g., the bit-line BL corresponding to the first layer S1) may be connected to the first end of each of the semiconductor patterns SP of the first layer S1. In one example, the bit-line BL may be directly connected to the first impurity areas SD1. In another example, the bit-line BL may be electrically connected to the first impurity area SD1 via metal silicide (not shown). Specific descriptions about each of the second layer S2 and the third layer S3 may be substantially the same as those about the first layer S1 as set forth above.

The gate electrode GE may have a line shape or a bar shape extending in the third direction D3. The gate electrodes GE may be stacked (e.g., arranged) so as to be spaced apart from each other along the first direction D1. Each gate electrode GE may extend in the third direction D3 and across the stack structure SS. In other words, the gate electrode GE may act as the word-line WL as described with reference to FIG. 1.

In a semiconductor memory device according to an example embodiment, the gate electrode GE may include a first gate electrode GE1 disposed on a first sidewall (e.g., one of both opposing sidewalls) of the semiconductor pattern SP, and a second gate electrode GE2 disposed on a second sidewall (e.g., the other of both opposing sidewalls) of the semiconductor pattern SP. The first side wall and the second side wall may face each other in the first direction D1.

A semiconductor memory device according to an example embodiment may have a double gate transistor structure. In a semiconductor memory device according to an example embodiment, a gate electrode GE may be disposed on a respective one of both opposing sidewalls of the semiconductor pattern SP.

The gate electrode GE may include a conductive material. For example, the gate electrode GE may include at least one of a doped semiconductor material (doped silicon, doped silicon-germanium, doped germanium, etc.), a conductive metal nitride (titanium nitride, tantalum nitride, etc.), a metal (tungsten, titanium, tantalum, etc.), or a metal-semiconductor compound (tungsten silicide, cobalt silicide, titanium silicide, etc.).

A gate insulating film GI may be interposed between the gate electrode GE and the semiconductor patterns SP. The gate insulating film GI may include at least one of a high dielectric constant insulating film, a silicon oxide film, a silicon nitride film, or a silicon oxynitride film. In one example, the high dielectric constant insulating film may be made of, for example, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or combinations thereof. However, the present disclosure is not limited thereto.

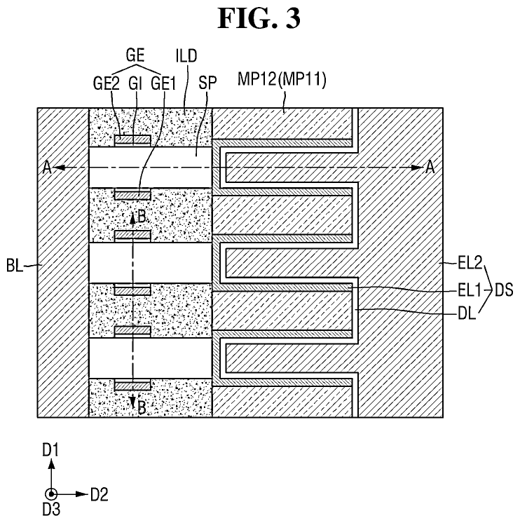

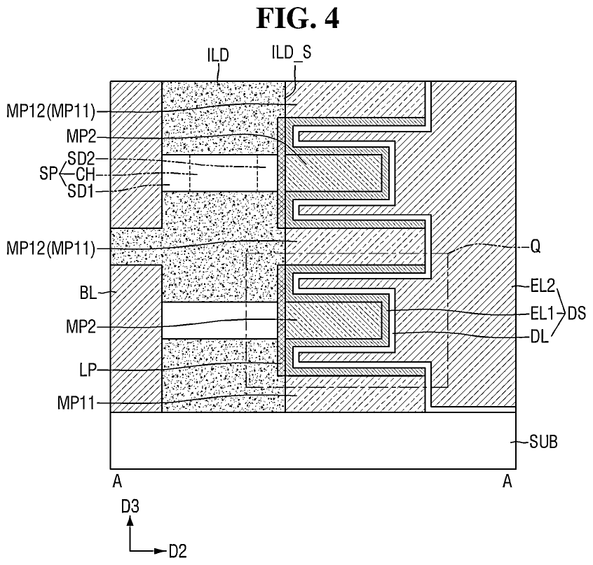

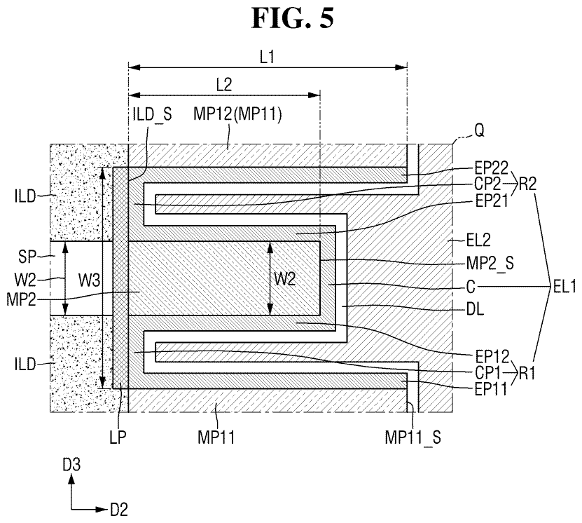

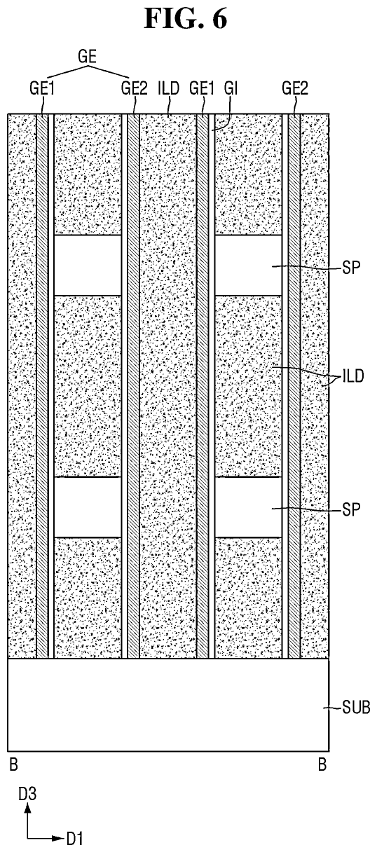

FIG. 3 is a top view showing a semiconductor memory device according to an example embodiment. FIG. 4 is a cross-sectional view cut along A-A in FIG. 3. FIG. 5 is an enlarged view of a Q portion of FIG. 4. FIG. 6 is a cross-sectional view cut along B-B in FIG. 3. For reference, FIG. 2 may show a portion of the sub-cell array SCA of the semiconductor memory device as described in FIG. 1. For convenience of description, descriptions that duplicate with those set forth above with reference to FIG. 1 and FIG. 2 are briefly described and following descriptions are mainly based on differences therebetween.

Referring to FIGS. 3 to 6, a semiconductor memory device according to an example embodiment includes the semiconductor pattern SP, an insulating film ILD, the bit-line BL, the gate electrode GE, and a first mold pattern MP11 and MP12, a second mold pattern MP2, and the information storage element DS.

The insulating film ILD is disposed on the substrate SUB. The insulating film ILD may fill an empty space within the stack structure SS in FIG. 2. The bit-line BL, the semiconductor pattern SP, and the landing pad LP may be disposed in the insulating film ILD. The insulating film ILD may have a multiple insulating film structure.

For example, the insulating film ILD may include at least one of a silicon oxide film, a silicon nitride film, or a silicon oxynitride film.

The insulating film ILD may not cover one side surface of the landing pad LP so as to be exposed. The first mold pattern MP11 and MP12, the second mold pattern MP2, and the information storage element DS may be disposed on the exposed side surface of the landing pad LP and a side wall ILD_S of the insulating film ILD aligned with the exposed side surface of the landing pad LP.

The first mold patterns MP11 and MP12 and the second mold patterns MP2 are arranged alternately with each other and are spaced apart from each other while being disposed on the substrate SUB. One second mold pattern MP2 is disposed between the two first mold patterns MP11 and MP12. The first mold pattern MP11 disposed under the second mold pattern MP2 may be referred to as a first-first mold pattern, and the first mold pattern MP12 disposed on top of the second mold pattern MP2 may be referred to as a first-second mold pattern. The first mold pattern MP11 may be referred to as the first-first mold pattern relative to the second mold pattern MP2 disposed on top of the first mold pattern MP11, and MP12 may be referred to as the first-second mold pattern relative to the second mold pattern MP2 disposed under the first mold pattern MP11.

The first mold pattern MP11 and MP12 and the second mold pattern MP2 extend from the side wall ILD_S of the insulating film ILD in the second direction D2. In the second direction D2, a length L1 of the first mold pattern MP11 and MP12 and a length L2 of the second mold pattern MP2 are different from each other. The length L1 of the first mold pattern MP11 and MP12 is larger than the length L2 of the second mold pattern MP2. The first mold pattern MP11 and MP12 protrudes in the second direction D2 beyond the second mold pattern MP2. This may result from a process of forming the first mold pattern MP11 and MP12 and the second mold pattern MP2.

In the third direction D3, a relationship between a width of the first mold pattern MP11 and MP12, a width W2 of the second mold pattern MP2, and a spacing between the first mold pattern MP11 or MP12 and the second mold pattern MP2 adjacent to each other may vary. In the third direction D3, the width of the first mold pattern MP11 and MP12, the width W2 of the second mold pattern MP2, and the spacing between the first mold pattern MP11 or MP12 and the second mold pattern MP2 adjacent to each other may be different from each other. In some example embodiments, at least two of them may be substantially equal to each other.

In the same etch process, the first mold pattern MP11 and MP12 may include a material with a lower etch rate than an etch rate of a material of the second mold pattern MP2.

For example, the first mold pattern MP11 and MP12 may include a silicon nitride film, and the second mold pattern MP2 may include a silicon oxynitride film or a carbon-containing silicon oxynitride film. In some example embodiment, the first mold pattern MP11 and MP12 and the second mold pattern MP2 may include a silicon nitride film, wherein a composition of the first mold pattern MP11 and MP12 may be different from a composition of the second mold pattern MP2. A concentration of silicon in the first mold pattern MP11 and MP12 may be different from a concentration of silicon in the second mold pattern MP2.

For example, the first mold pattern MP11 and MP12 may include silicon (Si), and the second mold pattern MP2 may include silicon-germanium (SiGe).

The information storage elements DS are disposed on the sidewall ILD_S of the insulating film ILD. The information storage element DS may include a first electrode EL1, a dielectric film DL, and a second electrode EL2. The first electrode EL1 may be spaced apart from the second electrode EL2. The dielectric film DL may be interposed between the first electrode EL1 and the second electrode EL2. The information storage element DS may be connected to the semiconductor pattern SP. The first electrode EL1 may be connected to the semiconductor pattern SP.

The information storage elements DS electrically connected to the semiconductor patterns SP stacked in the third direction D3 may share one dielectric film DL and one second electrode EL2. In other words, a plurality of first electrodes EL1 connected to the semiconductor patterns SP stacked in the third direction D3, respectively, may be stacked in the third direction. One dielectric film DL may be formed along surfaces of the plurality of first electrodes EL1. Furthermore, one second electrode EL2 may be disposed on one dielectric film DL. The first electrode EL1 may be electrically connected to the second impurity area SD2 of the semiconductor pattern SP.

The first electrode EL1 may be disposed between the first-first mold pattern MP11 and the -second mold pattern MP12. The first electrode EL1 may extend along an upper surface of the first-first mold pattern MP11, an outer surface (e.g., an upper surface, a lower surface, and a side surface) of the second mold pattern MP2, and a lower surface of the first-second mold pattern MP12. The first electrode EL1 may not cover a side surface of the first-first mold pattern MP11 and a side surface of the first-second mold pattern MP12 so as to be exposed.

For example, the first electrode EL1 includes a first area R1, a second area R2, and a connection area C. The first area R1 and the second area R2 are arranged to be spaced apart from each other in the third direction D3 while being disposed on the substrate SUB.

The first area R1 is disposed between the first-first mold pattern MP11 and the second mold pattern MP2. The first area R1 includes a first-first extension EP11, a first-second extension EP12, and a first connection portion CP1. The first-first extension EP11 and the first-second extension EP12 may extend in the second direction D2. The first-first extension EP11 may extend along the upper surface of the first-first mold pattern MP11. The first-second extension EP12 may extend along the lower surface of the second mold pattern MP2. In the second direction D2, a length of the first-first extension EP11 may be larger than a length of the first-second extension EP12. The first connection portion CP1 may extend in the third direction D3. The first connection portion CP1 may extend along the side wall ILD_S of the insulating film ILD. The first connection portion CP1 connects the first-first extension EP11 and the first-second extension EP12 to each other. That is, the first area R1 may have a ‘⊂’ shape in a plan view including the second direction D2 and the third direction D3.

The second area R2 is disposed between the second mold pattern MP2 and the first-second mold pattern MP12. The second area R2 includes a second-first extension EP21, a second-second extension EP22, and a second connection portion CP2. The second-first extension EP21 and the second-second extension EP22 may extend in the second direction D2. The second-first extension EP21 may extend along the upper surface of the second mold pattern MP2. The second-second extension EP22 may extend along the lower surface of the first-second mold pattern MP12. In the second direction D2, a length of the second-first extension EP21 may be smaller than a length of the second-second extension EP22. The second connection portion CP2 may extend in the third direction D3. The second connection portion CP2 may extend along the side wall ILD_S of the insulating film ILD. The second connection portion CP2 connects the second-first extension EP21 and the second-second extension EP22 to each other. That is, the second area R2 may have a ‘⊂’ shape in a plan view including the second direction D2 and the third direction D3.

The connection area C connects the first area R1 and the second area R2 to each other. The connection area C may extend in the third direction D3. The connection area C may extend along the side surface of the second mold pattern MP2. The connection area C connects the first-second extension EP12 and the second-first extension EP21 to each other. The connection area C is not physically connected to the first connection portion CP1 and the second connection portion CP2. The connection area C does not overlap with the first connection portion CP1 and the second connection portion CP2 in the third direction D3.

In a semiconductor memory device according to an example embodiment, a landing pad LP is disposed between the semiconductor pattern SP and the information storage element DS. The landing pad LP may include a conductive material.

The landing pad LP may be disposed within the insulating film ILD. The landing pad LP may not be covered with the side wall ILD_S of the insulating film ILD. The first mold pattern MP11 and MP12, the second mold pattern MP2, and the first electrode EL1 may be disposed on the landing pad LP. In the third direction D3, a width W3 of the landing pad LP may be greater than each of a width W1 of the semiconductor pattern SP and a width W2 of the second mold pattern MP2. The landing pad LP may contact at least a portion of the first connection portion CP1 and at least a portion of the second connection portion CP2 of the first electrode EL1. The first connection portion CP1 and the second connection portion CP2 of the first electrode EL1 are electrically connected to the semiconductor pattern SP via the landing pad LP.

The dielectric film DL may extend along a profile of the first electrode EL1 and the side surface of the first mold pattern MP11 and MP12 not covered with the first electrode EL1. The dielectric film DL may extend along the upper surface of the substrate SUB.

The second electrode EL2 may be disposed on the dielectric film DL. The second electrode EL2 may cover the first electrode EL1. The second electrode EL2 may fill a space defined by the first area R1 of the first electrode EL1 and a space defined by the second area R2 of the first electrode EL1. That is, the second electrode EL2 may include portions protruding toward the first electrode EL1.

Each of the first electrode EL1 and the second electrode EL2 may include, for example, a doped semiconductor material, conductive metal nitride (e.g., titanium nitride, tantalum nitride, niobium nitride or tungsten nitride, etc.), metal (e.g., ruthenium, iridium, titanium or tantalum, etc.), or conductive metal oxide (e.g., iridium oxide or niobium oxide, etc.). In this regard, each of the conductive metal nitride, the metal, and the conductive metal oxide may be included in a metallic conductive material.

For example, the dielectric film DL may be made of, for example, a high dielectric constant material. The high dielectric constant material may include, for example, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or combinations thereof. In a semiconductor memory device according to an example embodiment, the dielectric film DL may include a stacked film structure in which a zirconium oxide film, an aluminum oxide film, and a zirconium oxide film are sequentially stacked.

In a semiconductor memory device according to an example embodiment, the first electrode EL1 includes the first area R1 formed between two mold patterns MP11 and MP2, the second area R2 formed between two mold patterns MP2 and MP12, and the connection area C connecting the first area R1 and the second area R2 to each other. Therefore, an area in which the first electrode EL1 and the second electrode EL2 face each other increases, thereby increasing capacitance of the capacitor.

When forming, between two mold patterns having the same length, a capacitor including two extensions extending in the horizontal direction (e.g., the second direction D2) and a connection portion connecting the two extensions to each other, in order to increase the capacitance of the capacitor, lengths of the two mold patterns may be increased. In this case, lengths (lengths in the horizontal direction) of the two extensions may be increased. In this case, because the lengths of the two mold patterns are large, it may be difficult to form the first electrode EL1 and/or the dielectric film DL conformally.

However, in the semiconductor memory device according to an example embodiment, the first electrode EL1 includes the first area R1, the second area R2, and the connection area C. Thus, although the length of each of the extensions EP11, EP12, EP21, and EP22 may be smaller than the length of the extension of the capacitor (including the two extensions and the connection portion) as described above, the capacitance may be the same as the capacitor as described above may be achieved. Therefore, while the capacitance of the capacitor is maintained, the first electrode EL1 and/or the dielectric film DL may be formed more conformally. Furthermore, difficulty in the manufacturing process of the capacitor or a manufacturing time thereof may be reduced.

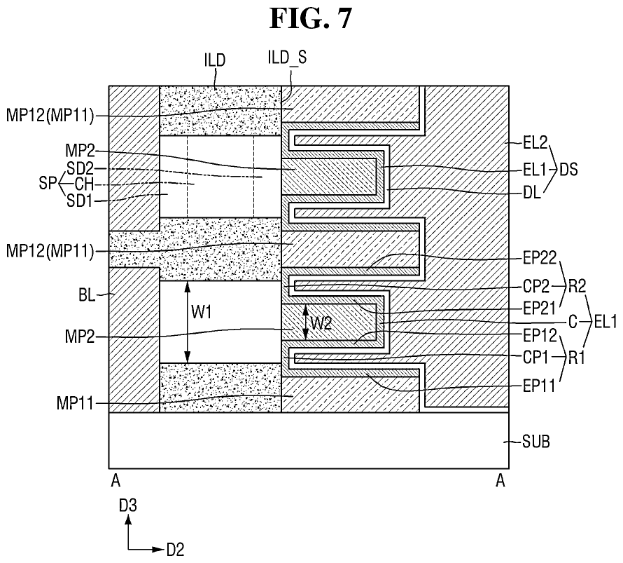

FIG. 7 is a diagram for illustrating a semiconductor memory device according to an example embodiment. For reference, FIG. 7 is a cross-sectional view cut along A-A in FIG. 3. For convenience of description, descriptions that duplicate with those set forth above using FIGS. 1 to 6 are briefly set forth, and following descriptions are made mainly based on differences therebetween.

Referring to FIG. 7, in the semiconductor memory device according to an example embodiment, the landing pad (LP in FIG. 4) is not disposed between the semiconductor pattern SP and the information storage element DS.

One side wall of the second impurity area SD2 of the semiconductor pattern SP may not be covered with the side wall ILD_S of the insulating film ILD. In the third direction D3, the width W1 of the semiconductor pattern SP may be greater than the width W2 of the second mold pattern MP2. The semiconductor pattern SP may contact at least a portion of the first connection portion CP1 and at least a portion of the second connection portion CP2 of the first electrode EL1. The first connection portion CP1 and the second connection portion CP2 of the first electrode EL1 are electrically connected to the semiconductor pattern SP.

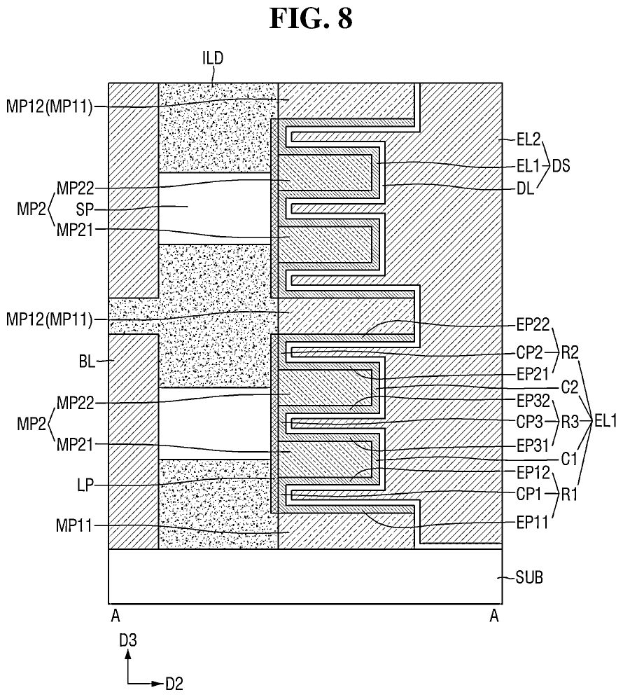

FIG. 8 is a diagram for illustrating a semiconductor memory device according to an example embodiment. For reference, FIG. 8 is a cross-sectional view cut along A-A in FIG. 3. For convenience of description, descriptions that duplicate with those set forth above using FIGS. 1 to 6 are briefly set forth, and following descriptions are made mainly based on differences therebetween.

Referring to FIG. 8, in the semiconductor memory device according to an example embodiment, the second mold pattern MP2 includes a plurality of sub-mold patterns MP21 and MP22 spaced apart from each other in the third direction D3. For example, the second mold pattern MP2 may include the first sub-mold pattern MP21 and the second sub-mold pattern MP22 spaced apart from each other in the third direction D3. Hereinafter, an example including two sub-mold patterns MP21 and MP22 is described. However, the number of sub-mold patterns MP21 and MP22 may be three or more.

In the third direction D3, a relationship between a width of the first sub-mold pattern MP21, a width of the second sub-mold pattern MP22, and a spacing between the first sub-mold pattern MP21 and the second sub-mold pattern MP22 may vary. In the third direction D3, the width of the first sub-mold pattern MP21, the width of the second sub-mold pattern MP22, and the spacing between the first sub-mold pattern MP21 and the second sub-mold pattern MP22 may be different from each other, or at least two of them may be substantially the same.

The first electrode EL1 may extend along the upper surface of the first-first mold pattern MP11, an outer surface (e.g., an upper surface, a lower surface, and a side surface) of the first sub-mold pattern MP21, an outer surface (e.g., an upper surface, a lower surface, and a side surface) of the second sub-mold pattern MP22, and the lower surface of the first-second mold pattern MP12.

For example, the first electrode EL1 includes the first area R1, the second area R2, a third area R3, a first connection area C1, and a second connection area C2. The third area R3 may be disposed between the first area R1 and the second area R2. The first area R1, the third area R3, and the second area R2 are sequentially arranged to be spaced apart from each other in the third direction D3 while being disposed on the substrate SUB.

The first area R1 is disposed between the first-first mold pattern MP11 and the first sub-mold pattern MP21. The first-second extension EP12 extends along the lower surface of the first sub-mold pattern MP21. The second area R2 is disposed between the first sub-mold pattern MP21 and the second sub-mold pattern MP22. The third area R3 is disposed between the second sub-mold pattern MP22 and the first-second mold pattern MP12.

The third area R3 includes a third-first extension EP31, a third-second extension EP32, and a third connection portion CP3. The third-first extension EP31 and third-second extension EP32 may extend in the second direction D2. The third-first extension EP31 may extend along the upper surface of the first sub-mold pattern MP21. The third-second extension EP32 may extend along the lower surface of the second sub-mold pattern MP22. The third connection portion CP3 connects the third-first extension EP31 and the third-second extension EP32 to each other.

The first connection area C1 connects the first area R1 and the third area R3 to each other. The first connection area C1 may extend in the third direction D3. The first connection area C1 may extend along the side surface of the first sub-mold pattern MP21. The first connection area C1 connects the first-second extension EP12 and third-first extension EP31 to each other. The first connection area C1 is not directly or physically connected to the first connection portion CP1 and the third connection portion CP3. The first connection area C1 does not overlap with the first connection portion CP1 and the third connection portion CP3 in the third direction D3.

The second connection area C2 connects the third area R3 and the second area R2 to each other. The second connection area C2 may extend in the third direction D3. The second connection area C2 may extend along a side surface of the second sub-mold pattern EP22. The second connection area C2 connects the third-second extension EP32 and the second-first extension EP21 to each other. The second connection area C2 is not directly or physically connected to the second connection portion CP2 and the third connection portion CP3. The first connection area C1 does not overlap with the second connection portion CP2 and the third connection portion CP3 in the third direction D3.

The landing pad LP may contact at least a portion of the first connection portion CP1, at least a portion of the second connection portion CP2, and at least a portion of the third connection portion CP3 of the first electrode EL1. The first connection portion CP1, the second connection portion CP2, and the third connection portion CP3 of the first electrode EL1 are electrically connected to the semiconductor pattern SP via the landing pad LP.

The first sub-mold pattern MP21 and the second sub-mold pattern MP22 may include the same material. The first sub-mold pattern MP21 and the second sub-mold pattern MP22 may be etched together at the same etch rate in the same etching process. Accordingly, in the second direction D2, a length of first sub-mold pattern MP21 may be substantially the same as a length of the second sub-mold pattern MP22. In the second direction D2, a length of the third-first extension EP31 may be substantially equal to a length of the third-second extension EP32.

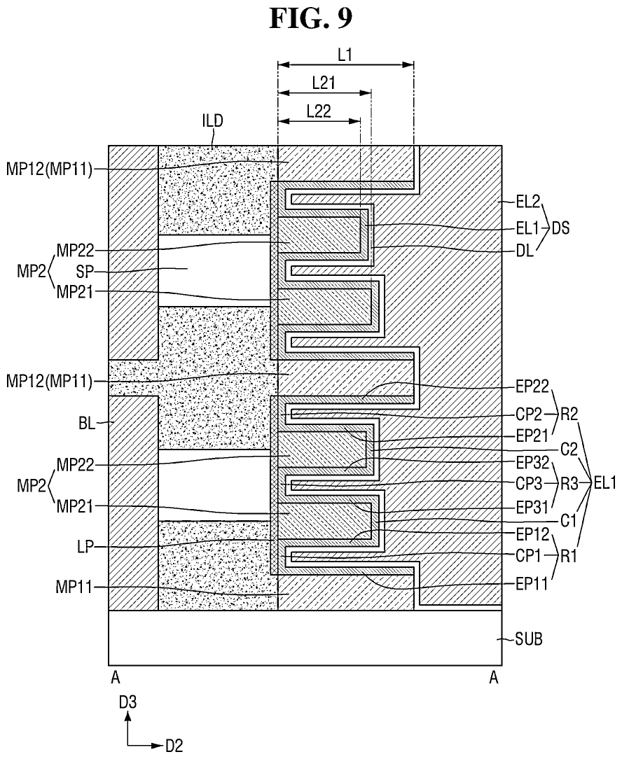

FIG. 9 is a diagram for illustrating a semiconductor memory device according to an example embodiment. For reference, FIG. 9 is a cross-sectional view cut along A-A in FIG. 3. For convenience of description, descriptions that duplicate with those set forth above using FIGS. 1 to 8 are briefly set forth, and following descriptions are made mainly based on differences therebetween.

Referring to FIG. 9, in a semiconductor memory device according to an example embodiment, the first sub-mold pattern MP21 and the second sub-mold pattern MP22 may include materials that may be etched together at different etch rates in the same etch process, respectively. In the same etching process, the etch rate of the first sub-mold pattern MP21 may be different from the etch rate of the second sub-mold pattern MP22. In the same etching process, the etch rate of the first sub-mold pattern MP21 may be higher than the etch rate of the first mold pattern MP11 and MP12 and may be lower than the etch rate of the second sub-mold pattern MP22. Accordingly, in the second direction D2, a length L21 of the first sub-mold pattern MP21 formed from the first mold film ML1 may be larger than a length L22 of the second sub-mold pattern MP22 formed from the second mold film ML2 and may be smaller than the length L1 of each of the first mold patterns MP11 and MP12. In the second direction D2, the length of the third-first extension EP31 may be larger than the length of the third-second extension EP32.

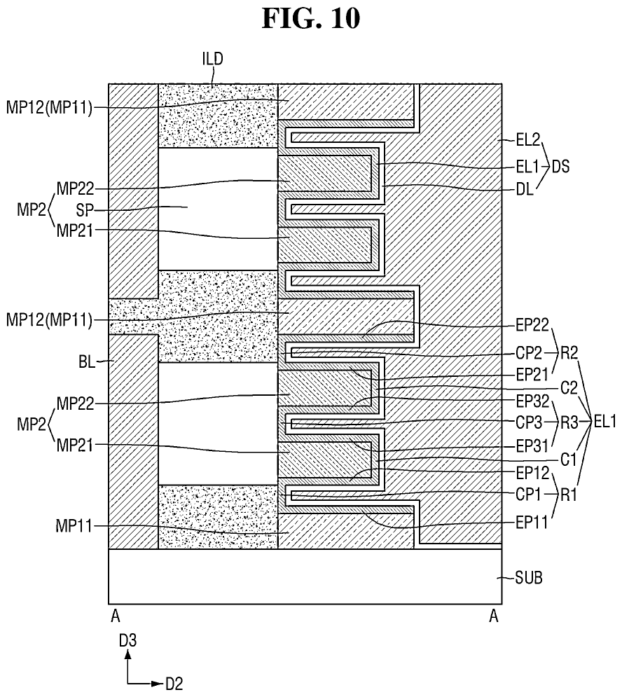

FIG. 10 is a diagram for illustrating a semiconductor memory device according to an example embodiment. For reference, FIG. 10 is a cross-sectional view cut along A-A in FIG. 3. For convenience of description, descriptions that duplicate with those set forth above using FIGS. 1 to 9 are briefly set forth, and following descriptions are made mainly based on differences therebetween.

Referring to FIG. 10, in the semiconductor memory device according to an example embodiment, the semiconductor pattern SP may contact at least a portion of the first connection portion CP1, at least a portion of the second connection portion CP2, and at least a portion of the third connection portion CP3 of the first electrode EL1. The first connection portion CP1, the second connection portion CP2, and the third connection portion CP3 of the first electrode EL1 are electrically connected to the semiconductor pattern SP.

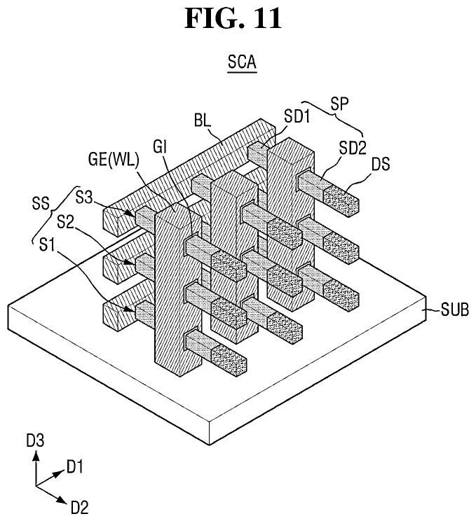

FIGS. 11 to 14 are respectively diagrams for illustrating semiconductor memory devices according to some example embodiments. For convenience of description, descriptions that duplicate with those set forth above using FIGS. 1 to 10 are briefly set forth, and following descriptions are made mainly based on differences therebetween.

Referring to FIG. 11, in a semiconductor memory device according to an example embodiment, the gate electrode GE may surround the channel area CH of the semiconductor pattern SP. The gate electrode GE may be provided on an upper surface, a bottom surface, and both opposing sidewalls of the channel area CH.

In a semiconductor memory device according to an example embodiment, the memory cell transistor may be a gate all-around transistor in which the gate electrode GE surrounds the channel area CH.

In some example embodiments, the gate electrode GE may include the first gate electrode GE1 and the second gate electrode GE2 as described above in FIG. 2, and a connection gate electrode connecting the first gate electrode GE1 and the second gate electrode GE2 to each other. The connection gate electrode may be disposed between semiconductor patterns SP spaced apart from each other in the third direction D3.

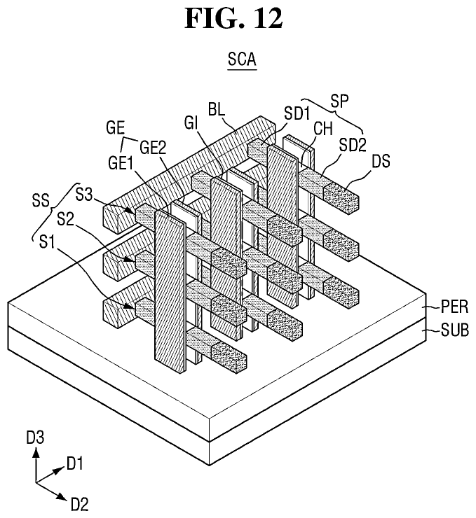

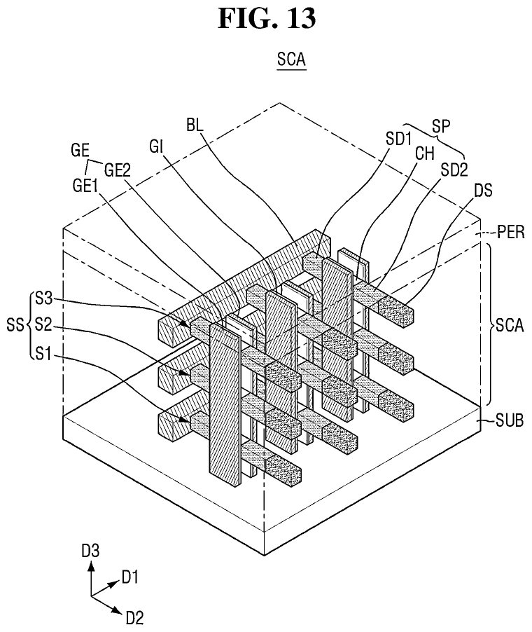

Referring to FIG. 12 and FIG. 13, in the semiconductor memory device according to some example embodiments, a peripheral circuit area PER and the sub-cell array SCA may be stacked in a vertical direction (e.g., in the third direction D3).

Referring to FIG. 12, in a semiconductor memory device according to an example embodiment, the peripheral circuit area PER may be disposed between the substrate SUB and the plurality of sub-cell arrays SCA.

The peripheral circuit area PER may include peripheral circuit transistors formed on the substrate SUB. The peripheral circuit area PER may include a circuit for operating a three-dimensional semiconductor memory device according to an example embodiment.

On the peripheral circuit area PER, the sub-cell array SCA as described above with reference to FIG. 2 may be disposed. For example, the stack structure SS including the first to third layers S1, S2, and S3 may be disposed on the peripheral circuit area PER.

A wiring layer electrically connected to the sub-cell array SCA may be electrically connected to the peripheral circuit area PER via, for example, a through-contact.

Referring to FIG. 13, in a semiconductor memory device according to an example embodiment, the sub-cell array SCA may be disposed on the substrate SUB. The peripheral circuit area PER may be disposed on the sub-cell array SCA.

As previously described, the peripheral circuit area PER may include the circuit for operating the sub-cell array SCA.

In one example, the peripheral circuit area PER may be electrically connected to the sub-cell array SCA via, for example, a through-contact.

In another example, the peripheral circuit area PER may include a peripheral circuit wiring layer that is electrically connected to the circuit for operating the sub-cell array SCA. The wiring layer electrically connected to the sub-cell array SCA may be positioned to face the peripheral circuit wiring layer of the peripheral circuit area PER. Using a wafer bonding method, the wiring layer electrically connected to the sub-cell array SCA may be electrically connected to the peripheral circuit wiring layer of the peripheral circuit area PER.

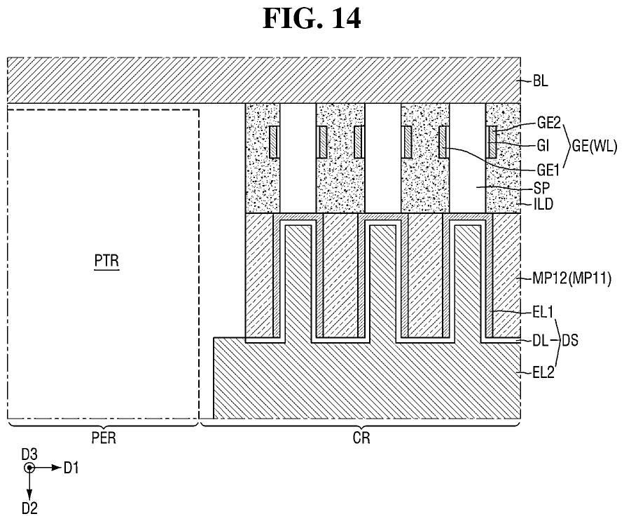

Referring to FIG. 14, a semiconductor memory device according to an example embodiment may include a cell area CR where the cell array (CA in FIG. 1) as described above with reference to FIG. 1 is disposed and a peripheral circuit area PER where peripheral transistors PTR are disposed. The peripheral transistors PTR may be connected to the cell array (CA in FIG. 1) via the bit-lines BL. The cell area CR and the peripheral circuit area PER may be arranged in a parallel direction (e.g., the first direction D1 or the second direction D2) to the upper surface of the substrate.

The bit-lines BL may extend from the cell area CR to the peripheral circuit area PER. The bit-lines BL may extend in the first direction D1, but may have different lengths. For example, the bit-lines BL may have a stepwise structure in the peripheral circuit area PER.

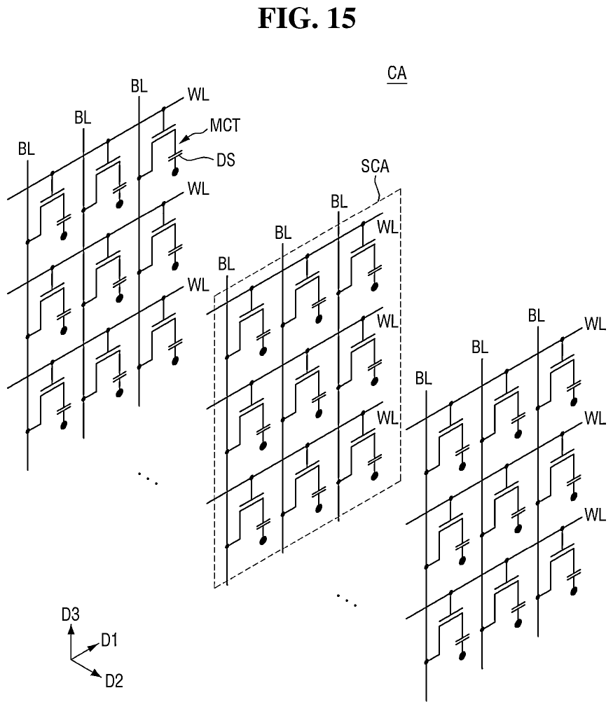

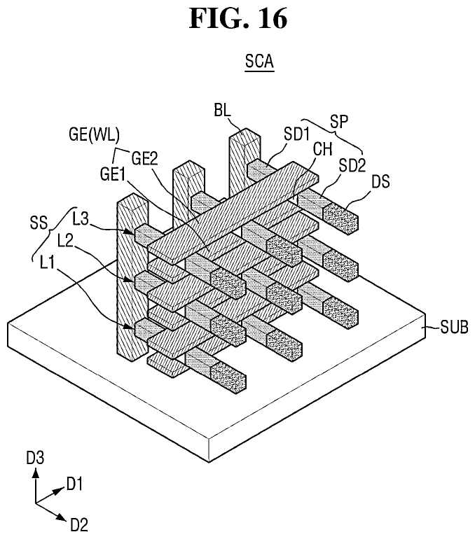

FIG. 15 is a schematic circuit diagram showing a cell array of a 3D semiconductor memory device according to an example embodiment. FIG. 16 is an illustrative perspective view showing a semiconductor memory device according to an example embodiment. For convenience of description, descriptions that duplicate with those set forth above using FIGS. 1 and 2 are briefly set forth, and following descriptions are made mainly based on differences therebetween.

Referring to FIG. 15, in the semiconductor memory device according to an example embodiment, the bit-lines BL may be conductive patterns (e.g., metal lines) extending in the direction (that is, the third direction D3) perpendicular to the substrate. Bit lines BL within one sub-cell array SCA may be arranged in the first direction D1. Adjacent bit-lines BL may be spaced apart from each other in the first direction D1.

The word-lines WL may be conductive patterns (e.g., metal lines) stacked on the substrate in the third direction D3. Each word-line WL may extend in the first direction D1. Adjacent word-lines WL may be spaced apart from each other in the third direction D3.

Referring to FIG. 15 and FIG. 16, one of the plurality of sub-cell arrays SCA as described above with reference to FIG. 15 may be disposed on the substrate SUB.

The bit-line BL may be electrically connected to the first impurity areas SD1 of the semiconductor patterns SP arranged along the third direction D3.

In an example embodiment, each gate electrode GE may include a first gate electrode GE1 disposed on a first sidewall as one of both opposing sidewalls of the semiconductor pattern SP, and a second gate electrode GE2 disposed on a second sidewall as the other of both opposing sidewalls of the semiconductor pattern SP. The first sidewall and the second sidewall may be opposite to each other in the third direction D3.

In an example embodiment, the gate electrode GE may be disposed on one of both opposing sidewalls of the semiconductor patterns SP. In an example embodiment, the gate electrode GE may surround the channel area CH.

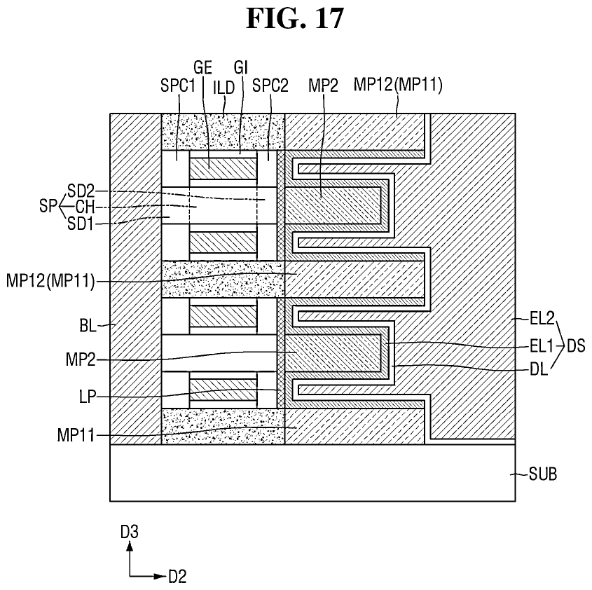

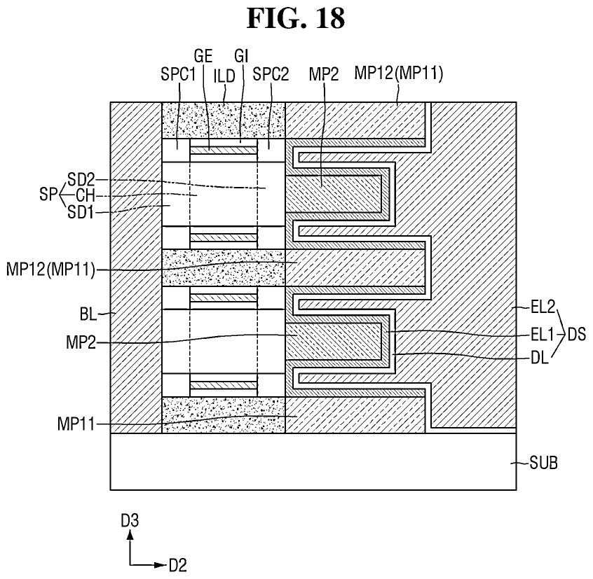

FIG. 17 and FIG. 18 are diagrams for illustrating a semiconductor memory device according to some example embodiments. For reference, FIG. 17 and FIG. 18 may be illustrative cross-sectional views of the semiconductor pattern SP stacked in the third direction D3 in FIG. 16 as cut along the second direction D2. For convenience of description, descriptions that duplicate with those set forth above using FIGS. 1 to 16 are briefly set forth, and following descriptions are made mainly based on differences therebetween.

Referring to FIG. 17 and FIG. 18, a first spacer pattern SPC1 may be disposed between the semiconductor pattern SP and the insulating film ILD. The first spacer pattern SPC1 may be disposed on the upper and lower surfaces of the semiconductor pattern SP. The first spacer pattern SPC1 may spatially separate the gate electrode GE and the bit-line BL from each other.

A second spacer pattern SPC2 may be disposed between the semiconductor pattern SP and the insulating film ILD. The second spacer pattern SPC2 may be disposed on the upper and lower surfaces of the semiconductor pattern SP. The second spacer pattern SPC2 may be disposed between the gate electrode GE and the information storage element DS.

In some example embodiments, the gate insulating film GI may be interposed between the first spacer pattern SPC1 and the semiconductor pattern SP, between the first spacer pattern SPC1 and the insulating film ILD, between the second spacer pattern SPC2 and the semiconductor pattern SP, and between the second spacer pattern SPC2 and the insulating film ILD. The gate insulating film GI may be interposed between the gate electrode GE and the second spacer pattern SPC2, or the second spacer pattern SPC2 may be omitted.

Each of the first spacer pattern SPC1 and the second spacer pattern SPC2 may include at least one of, for example, a silicon oxide film, a silicon nitride film, a silicon oxynitride film, a carbon-containing silicon oxide film, a carbon-containing silicon nitride film, or a carbon-containing silicon oxynitride film.

Referring to FIG. 17, in a semiconductor memory device according to an example embodiment, the landing pad LP is disposed between the semiconductor pattern SP and the information storage element DS. The landing pad LP may contact at least a portion of the first connection portion CP1 and at least a portion of the second connection portion CP2 of the first electrode EL1. The first connection portion CP1 and the second connection portion CP2 of the first electrode EL1 are electrically connected to the semiconductor pattern SP via the landing pad LP.

Referring to FIG. 18, in the semiconductor memory device according to an example embodiment, the landing pad (LP in FIG. 4) is not disposed between the semiconductor pattern SP and the information storage element DS. The semiconductor pattern SP may contact at least a portion of the first connection portion CP1 and at least a portion of the second connection portion CP2 of the first electrode EL1. The first connection portion CP1 and the second connection portion CP2 of the first electrode EL1 are electrically connected to the semiconductor pattern SP.

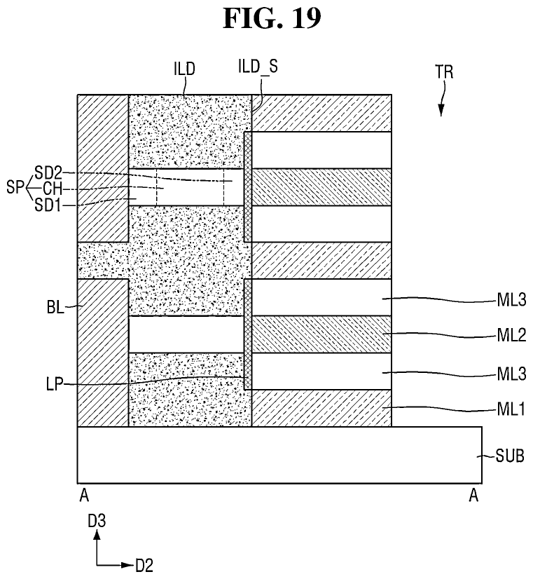

FIGS. 19 to 23 are diagrams for illustrating a method for manufacturing method a semiconductor memory device according to some embodiments. For reference, FIGS. 19 to 23 are cross-sectional views cut along A-A in FIG. 3.

Hereinafter, the manufacturing process may be a process that proceeds after the bit-line BL and the gate electrode GE have been formed. However, the present disclosure is not limited thereto, and, the information storage element DS may be formed, and then, the bit-line BL and/or the gate electrode GE may be formed.

Referring to FIG. 19, the insulating film ILD having the bit-line BL, the semiconductor pattern SP, and the landing pad LP formed therein may be provided on the substrate SUB. At least a portion of the landing pad LP may not be covered with the side wall ILD_S of the insulating film ILD.

On the substrate SUB, the first mold films ML1, the second mold films ML2, and third mold films ML3 may be formed. The first mold film ML1 and the second mold film ML2 may be stacked on the substrate SUB while being spaced apart from each other in the third direction D3. The third mold film ML3 may be disposed between the first mold film ML1 and the second mold film ML2 that are adjacent to each other.

The first mold films ML1, the second mold films ML2, and the third mold films ML3 may be formed on the sidewall ILD_S of the insulating film ILD. At least a portion of the third mold film ML3 disposed on top of one second mold film ML2, at least a portion of the third mold film ML3 disposed under the one second mold film ML2, and the one second mold film ML2 may overlap the landing pad LP in the second direction D2. One landing pad LP may contact two third mold films ML3 that are disposed on above and under one second mold film ML2, respectively.

In the third direction D3, a relationship between a thickness of the first mold film ML1, a thickness of the second mold film ML2, and a thickness of the third mold film ML3 may vary.

The first mold films ML1, the second mold films ML2, and the third mold films ML3 may include a trench TR. The trench TR may expose an upper surface of the substrate SUB.

In the same etching process, the etch rate of the first mold film ML1 may be lower than the etch rate of the second mold film ML2, and the etch rate of the second mold film ML2 may be lower than the etch rate of the third mold film ML3. That is, in the same etching process, the etch rate of the second mold film ML2 may be present between the etch rate of the first mold film ML1 and the etch rate of the third mold film ML3. The second mold film ML2 and the third mold film ML3 may respectively include materials that may be etched together at different etch rates in the same etching process.

For example, the first mold film ML1 may include a silicon nitride layer, and the third mold film ML3 may include a silicon oxide layer. The second mold film ML2 may include a silicon oxynitride film or a carbon-containing silicon oxynitride film. In some example embodiments, each of the first mold film ML1 and the second mold film ML2 may include a silicon nitride film, wherein a composition of the first mold film ML1 may be different from a composition of the second mold film ML2. A concentration of silicon in the first mold film ML1 may be different from a concentration of silicon in the second mold film ML2.

For example, the first mold film ML1 may include silicon (Si), and each of the second mold film ML2 and third mold film ML3 may include silicon-germanium (SiGe). The composition of the second mold film ML2 may be different from the composition of the third mold film ML3. The concentration of silicon in the second mold film ML2 may be different from that in the third mold film ML3. The concentration of silicon in the second mold film ML2 may be greater than the concentration of silicon in the third mold film ML3.

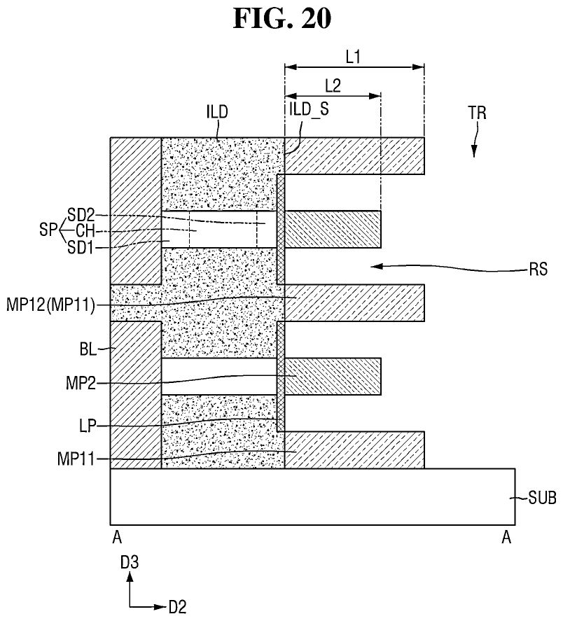

Referring to FIG. 19 and FIG. 20, the third mold film ML3 exposed through the trench TR may be removed.

In the process of removing the third mold film ML3, the etch rate of the second mold film ML2 may be present between the etch rate of the first mold film ML1 and the etch rate of the third mold film ML3. In the process of removing the third mold film ML3, the second mold film ML2 may be etched at a lower etch rate than an etch rate at which the third mold film ML3 is etched, and the first mold film ML1 may be barely etched or may be etched at a lower etch rate than an etch rate at which the second mold film ML12 is etched. Accordingly, in the second direction D2, the length L1 of the first mold pattern MP11 and MP12 formed from the first mold film ML1 may be larger than the length L2 of the second mold pattern MP2 formed from the second mold film ML2.

A recess RS may be formed by removing an entirety of the third mold film ML3 and a portion of the second mold film ML2. At least a portion of the landing pad LP may be exposed through the recess RS. The recess RS may extend from the trench TR toward the bit-line BL. The recess RS may be defined by the first mold pattern MP11 and MP12, the second mold pattern MP2, and the landing pad LP.

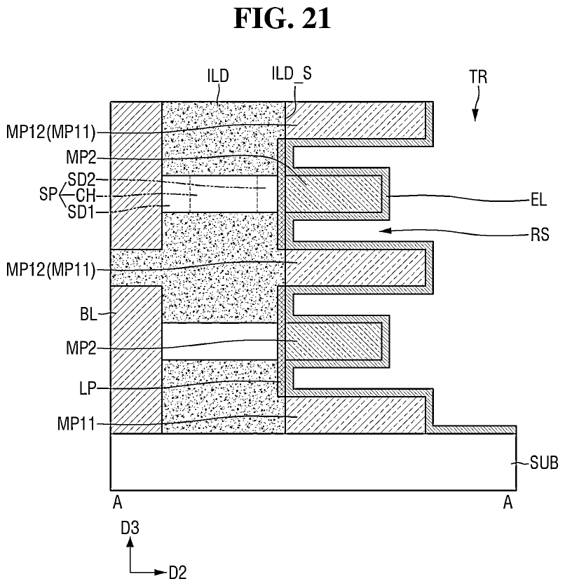

Referring to FIG. 21, an electrode film EL may be formed along a profile of the trench TR and a profile of the recess RS. The electrode film EL may be formed along a portion exposed through the trench TR and the recess RS. The electrode film EL may extend along the upper surface of the substrate SUB, the outer surface (e.g., an upper surface, a lower surface, and a side surface) of the first mold patterns MP11 and MP12, the outer surface (e.g., an upper surface, a lower surface, and a side surface) of the second mold pattern MP2, and a portion of the landing pad LP exposed through the recess RS.

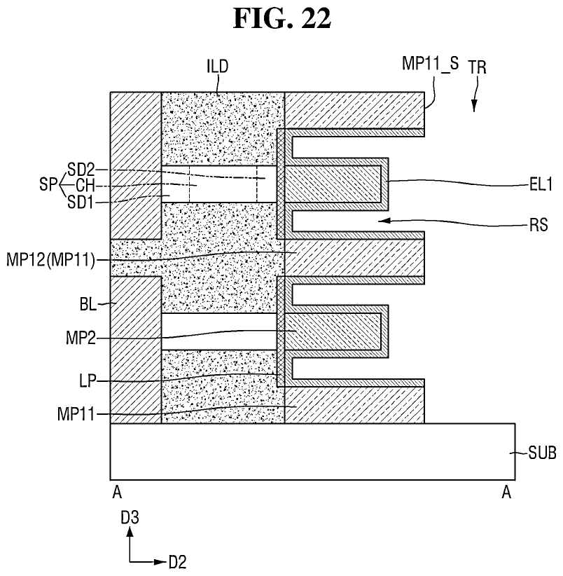

Referring to FIG. 21 and FIG. 22, a portion of the electrode film EL formed on the side surface of the first mold pattern MP11 and MP12 may be etched to form a plurality of first electrodes EL1 spatially separated from each other. At this time, a portion of the electrode film EL disposed on the side surface of the second mold pattern MP2 is not etched, and a portion of the electrode film EL formed on the upper surface of the substrate SUB may be etched. The electrode film EL may be etched using dry etching, etc.

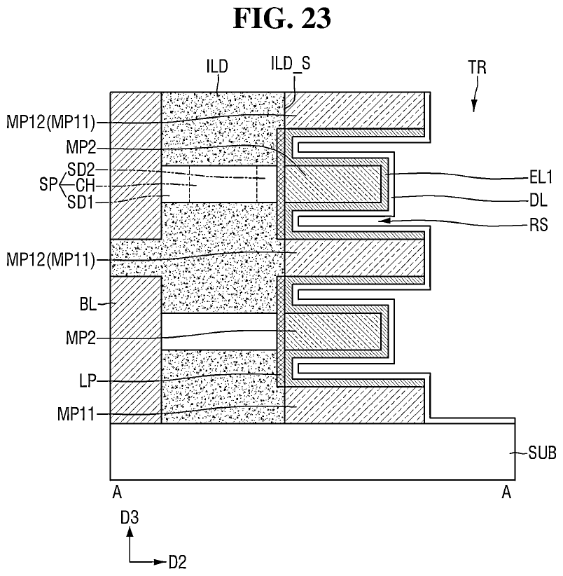

Referring to FIG. 23, the dielectric film DL may be formed on the first electrode EL1. The dielectric film DL may extend along the upper surface of the substrate SUB, the profile of the first electrode EL1, and the side surface of the first mold pattern MP11 and MP12 not covered with the first electrode EL1.

Referring to FIG. 23 and FIG. 4, the second electrode EL2 may be formed on the dielectric film DL. The second electrode EL2 may fill the trench TR and the recess RS. Accordingly, the information storage element DS may be formed.

Although some example embodiments of the present disclosure have been described with reference to the accompanying drawings, the present disclosure is not limited to the above example embodiments, but may be implemented in various different forms. A person skilled in the art may appreciate that the present disclosure may be practiced in other concrete forms without changing the technical spirit or essential characteristics of the present disclosure. Therefore, it should be appreciated that the example embodiments as described above are not restrictive but illustrative in all respects.

What is claimed is:

1. A semiconductor memory device comprising:
a semiconductor pattern on a substrate, and extending in a first direction parallel to an upper surface of the substrate;
a bit-line electrically connected to a first end of the semiconductor pattern;
a first electrode electrically connected to a second end of the semiconductor pattern, the second end of the semiconductor pattern being opposite to the first end of the semiconductor pattern;
a second electrode on the first electrode;
a dielectric film interposed between the first electrode and the second electrode; and
a gate electrode on the semiconductor pattern,
wherein the first electrode includes,
a first area and a second area spaced apart from each other in a second direction perpendicular to the upper surface of the substrate, and
a connection area connecting the first area and the second area to each other, wherein each of the first area and the second area includes,
a first extension and a second extension spaced apart from each other in the second direction, and
a connection portion connecting the first extension and the second extension to each other and physically separated from the connection area, and
wherein the connection area connects the second extension of the first area and the first extension of the second area that are adjacent to each other.

2. The semiconductor memory device of claim 1, wherein a length in the first direction of the first extension in the first direction is different from a length in the first direction of the second extension.

3. The semiconductor memory device of claim 2, wherein
the length in the first direction of the first extension of the first area is larger than the length in the first direction of the second extension of the first area, and
the length in the first direction of the first extension of the second area is smaller than the length in the first direction of the second extension of the second area.

4. The semiconductor memory device of claim 1, wherein at least a portion of the first electrode is in contact with the second end of the semiconductor pattern.

5. The semiconductor memory device of claim 4, wherein the connection portion of the first area and the connection portion of the second area are in contact with the second end of the semiconductor pattern.

6. The semiconductor memory device of claim 1, further comprising:
a landing pad between the first electrode and the second end of the semiconductor pattern.

7. The semiconductor memory device of claim 6, wherein the connection portion of the first area and the connection portion of the second area are in contact with the landing pad.

8. The semiconductor memory device of claim 1, wherein
the bit-line extends in the second direction, and
the gate electrode extends in a third direction parallel to the upper surface of the substrate and different from the first direction.

9. The semiconductor memory device of claim 1, wherein
the bit-line extends in a third direction parallel to the upper surface of the substrate and different from the second direction, and
the gate electrode extends in the second direction.

10. A semiconductor memory device comprising:
a bit-line on a substrate;
a semiconductor pattern extending from the bit-line in a first direction parallel to an upper surface of the substrate;
a first mold pattern, a second mold pattern, and a third mold pattern sequentially arranged and spaced apart from each other in a second direction perpendicular to the upper surface of the substrate, each of the first mold pattern, the second mold pattern, and the third mold pattern extending in the first direction, each of the first mold pattern and the third mold pattern protruding in the first direction beyond the second mold pattern; and
an information storage element on the first mold pattern, the second mold pattern, and the third mold pattern, the information storage element being electrically connected to the semiconductor pattern.

11. The semiconductor memory device of claim 10, wherein the information storage element includes:
a first electrode extending along the first mold pattern, the second mold pattern, and the third mold pattern;
a second electrode on the first electrode; and
a dielectric film between the first electrode and the second electrode.

12. The semiconductor memory device of claim 11, wherein a side surface of the first mold pattern and a side surface of the third mold pattern is exposed by the first electrode.

13. The semiconductor memory device of claim 10, wherein in a same etching process, each of an etch rate of the first mold pattern and an etch rate of the third mold pattern are lower than an etch rate of the second mold pattern.

14. The semiconductor memory device of claim 10, wherein the second mold pattern includes a first sub-mold pattern and a second sub-mold pattern spaced apart from each other in the second direction.

15. The semiconductor memory device of claim 14, wherein the first sub-mold pattern protrudes in the first direction beyond the second sub-mold pattern.

16. The semiconductor memory device of claim 10, further comprising:
a landing pad between the semiconductor pattern and the second mold pattern.

17. The semiconductor memory device of claim 16, wherein a width in the second direction of the landing pad is greater than a width in the second direction of the second mold pattern.

18. The semiconductor memory device of claim 10, wherein a width in the second direction of the semiconductor pattern is different from a width in the second direction of the second mold pattern.

19. A semiconductor memory device comprising:
a bit-line on a substrate;
a semiconductor pattern extending from the bit-line in a first direction parallel to an upper surface of the substrate;
a gate electrode on the semiconductor pattern;
a first mold pattern, a second mold pattern, and a third mold pattern sequentially arranged and spaced apart from each other in a second direction perpendicular to the upper surface of the substrate, each of the first mold pattern, the second mold pattern, and the third mold pattern extending in the first direction, each of the first mold pattern and the third mold pattern protruding in the first direction beyond the second mold pattern; and
an information storage element between the first mold pattern and the third mold pattern, and electrically connected to the semiconductor pattern,
wherein the information storage element includes,
a first electrode including,
a first area between the first mold pattern and the second mold pattern,
a second area between the second mold pattern and the third mold pattern, and
a connection area on a side surface of the second mold pattern and connecting the first area and the second area to each other,
a second electrode on the first electrode, and
a dielectric film interposed between the first electrode and the second electrode, and
wherein in a same etching process, each of an etch rate of the first mold pattern and an etch rate of the third mold pattern is different from an etch rate of the second mold pattern.

20. The semiconductor memory device of claim 19, wherein one of the bit-line and the gate electrode extends in the second direction, and the other one of the bit-line and the gate electrode extends in a third direction parallel to the upper surface of the substrate and different from the first direction.
